(19) United States
(12) Patent Application Publication
(10) Pub. No.: US 2012/0031466 A1
(43) Pub. Date: Feb. 9, 2012

(54) DEVICE AND METHOD FOR CONVERTING INCIDENT RADIATION INTO ELECTRICAL ENERGY USING AN UPCONVERSION PHOTOLUMINESCENT SOLAR CONCENTRATOR

(76) Inventor: Garrett Bruer, Hamel, MN (US)

(21) Appl. No.: 13/243,821

(22) Filed: Sep. 23, 2011

Related U.S. Application Data
(63) Continuation-in-part of application No. PCT/US2010/033400, filed on May 3, 2010.
(60) Provisional application No. 61/174,494, filed on May 1, 2009.

(51) Int. Cl. H01L 31/052; H01L 31/0232; G01N 21/64

(52) U.S. Cl. 136/246; 250/458.1; 136/259

(57) ABSTRACT

Device and method for converting incident radiation into electrical energy using an upconversion photoluminescent solar concentrator is disclosed. An upconversion photoluminescent solar concentrator device includes a waveguide. The waveguide has a waveguide medium. An upconversion chromophore is in contact with the waveguide medium. The upconversion chromophore is configured to absorb an incident photon. The upconversion chromophore is also configured to emit an emitted photon. The emitted photon has higher energy than the incident photon. A photovoltaic device absorbs the emitted photon, generating electricity.

### CROSS-REFERENCE TO RELATED APPLICATIONS

This application is a continuation-in-part of the PCT International Application No. PCT/US2010/033400 filed on May 3, 2010, the entire contents of which are hereby incorporated by reference.

This application claims priority of U.S. Provisional Application No. 61/174,494 filed on May 1, 2009, the entire contents of which are hereby incorporated by reference.

### FIELD

This description relates generally to an upconversion photoluminescent solar concentrator and a photovoltaic device connected to the upconversion photoluminescent solar concentrator.

### BACKGROUND

Light concentrators can considerably reduce the cost of electricity from photovoltaic (PV) cells. Conventional light concentrating devices and techniques utilize the direct component of radiation, thus requiring inefficient methods like solar tracking.

Light concentrating device for concentrating solar light using a fluorescent collector is known. The fluorescent collector converts high-frequency ultraviolet (UV) light to the visible light range through red-shifting (or via Stokes shift) the light for use by photovoltaic (PV) cells. The fluorescent collector may include a transparent sheet doped with organic dyes and/or inorganic compounds. The fluorescent collector is configured so that sunlight is absorbed by the dyes or compounds and then a photon is re-radiated isotropically. The re-radiated photon is then trapped in the sheet of the fluorescent collector by internal reflection, wherein the trapped photon may be converted at the edge of the sheet by a PV cell with a band-gap just below the luminescent energy. However, in the fluorescent collector, excess photon energy is dissipated in the collector by the luminescent red-shift (or Stokes' shift) rather than in the PV cell.

Because conventional concentrators can access only the UV spectrum, conventional concentrators use only a limited portion of the total solar spectrum. Accordingly, a large portion of the solar spectrum cannot be used by conventional concentrators for generating electricity. Further limiting the conventional concentrators is the fact that the atmosphere filters out a significant portion of UV light from the sun.

### BRIEF SUMMARY

An embodiment of an upconversion photoluminescent solar concentrator device includes a waveguide, which has a waveguide medium. The embodiment also includes an upconversion chromophore in contact with the waveguide medium. The upconversion chromophore is configured to absorb an incident photon. The upconversion chromophore is also configured to emit an emitted photon. The emitted photon has higher energy than the incident photon.

In another embodiment of the upconversion photoluminescent solar concentrator device, the upconversion chromophore is configured to absorb a second incident photon after the absorption of the incident photon and then emit the emitted photon, wherein the emitted photon has higher energy than the second incident photon.

In another embodiment of the upconversion photoluminescent solar concentrator device, the upconversion chromophore is configured to absorb the incident photon having a wavelength in infrared range, and then emit the emitted photon having a wavelength in visible, and/or near-infrared range.

In another embodiment of the upconversion photoluminescent solar concentrator device, the upconversion chromophore is embedded in the waveguide medium. In another embodiment of the upconversion photoluminescent solar concentrator device, the upconversion chromophore is provided at a surface of the waveguide medium. In another embodiment of the upconversion photoluminescent solar concentrator device, the upconversion chromophore is provided as a layer, a film, or a sheet, on a surface of the waveguide and/or a surface of the waveguide medium. In another embodiment of the upconversion photoluminescent solar concentrator device, the waveguide medium is a liquid, and the upconversion chromophore is suspended in the liquid.

In an embodiment of the upconversion photoluminescent solar concentrator device, the waveguide has a rod-like shape axially and a geometric cross-section.

In an embodiment of the upconversion photoluminescent solar concentrator device, the waveguide medium is transparent at a wavelength of the emitted photon. The waveguide medium is one selected from the group consisting of an amorphous silicon dioxide, a silicon dioxide, a clear plastic, a glass, an organic glass, a glass doped with a Group II-VI semiconductor and acrylic plastic.

In an embodiment of the upconversion photoluminescent solar concentrator device, the upconversion chromophore is an H-aggregate. An H-aggregate is used herein to describe a dye that shows a shift towards the blue or shows a hypsochromic shift. In an embodiment of the upconversion photoluminescent solar concentrator device, the upconversion chromophore is a rare-earth ion. Rare-earth ion is used herein to include a rare-earth ion nanocrystal. In an embodiment of the upconversion photoluminescent solar concentrator device, the upconversion chromophore is a rare-earth ion nanocrystal. Examples of the rare-earth ion nanocrystal are, but not limited to, neodymium (Nd³⁺), ytterbium (Yb³⁺), erbium (Er³⁺), thulium (Tm³⁺), holmium (Ho³⁺), praseodymium (Pr³⁺), cerium (Ce³⁺), yttrium (Y³⁺), samarium (Sm³⁺), europium (Eu³⁺), gadolinium (Gd³⁺), terbium (Tb³⁺), dysprosium (Dy³⁺), and lutetium (Lu³⁺). In an embodiment of the upconversion photoluminescent solar concentrator device, the upconversion chromophore is a lanthanide chelate. In an embodiment of the upconversion photoluminescent solar concentrator device, the upconversion chromophore is a NaYF₄ nanocrystal.

In another embodiment, the upconversion photoluminescent solar concentrator device further includes an antireflection coating provided on a side of the waveguide, and a taper provided on the antireflection coating, wherein a refractive index of the taper is higher than a refractive index of the waveguide medium.

In an embodiment of the upconversion photoluminescent solar concentrator device, the taper has a receiving surface towards the waveguide for receiving the emitted photon, and an output surface for outputting the emitted photon, wherein the output surface is smaller than the receiving surface.

In an embodiment of the upconversion photoluminescent solar concentrator device, the taper is a nanocrystalline diamond. In an embodiment of the upconversion photoluminescent solar concentrator device, the taper has a refractive index in a range of 2.0 to 2.6 inclusive.

In an embodiment of the upconversion photoluminescent solar concentrator device, a reflective surface is provided on a second side of the waveguide for reflecting the emitted photon towards the taper. In an embodiment of the upconversion photoluminescent solar concentrator device, a reflective surface is provided on multiple sides of the waveguide for reflecting the emitted photon towards the taper.

In an embodiment, the upconversion photoluminescent solar concentrator device also includes a photovoltaic device directly connected to the taper, wherein a refractive index of the photovoltaic device is higher than the refractive index of the taper. In an embodiment of the upconversion photoluminescent solar concentrator device, the photovoltaic device is a quantum dot, quantum well photovoltaic device, an AlGaAs/GaAs quantum well photovoltaic device, a direct band gap photovoltaic device, a silicon-based photovoltaic device, or a Group III-V direct band gap photovoltaic device. In an embodiment, the upconversion chromophore has an absorption spectrum and an emission spectrum that do not overlap. In an embodiment, the upconversion chromophore has an absorption spectrum and an emission spectrum that overlap.

In an embodiment, the upconversion photoluminescent solar concentrator device also includes a second upconversion chromophore, wherein the second upconversion chromophore absorbs a second incident photon and emits a second emitted photon. The second emitted photon has higher energy than the second incident photon, and the second incident photon has higher energy than the incident photon.

In an embodiment of the upconversion photoluminescent solar concentrator device, the upconversion chromophore has a first absorption spectrum and a first emission spectrum, wherein the first absorption spectrum and the first emission spectrum do not substantially overlap. The second upconversion chromophore has a second absorption spectrum and a second emission spectrum, and wherein the second absorption spectrum and the second emission spectrum do not substantially overlap.

In an embodiment of the upconversion photoluminescent solar concentrator device, the first absorption spectrum and the second absorption spectrum do not substantially overlap. In an embodiment, the first emission spectrum and the second emission spectrum overlap. In another embodiment of the upconversion photoluminescent solar concentrator device, the first emission spectrum and the second emission spectrum substantially overlap.

In an embodiment, the upconversion photoluminescent solar concentrator device includes a first waveguide and a second waveguide provided under the first waveguide. The first waveguide includes a first waveguide medium, and a first upconversion chromophore in contact with the first waveguide medium, wherein the first upconversion chromophore has a first absorption spectrum and a first emission spectrum, and wherein the first absorption spectrum and the first emission spectrum do not overlap. The second waveguide includes a second waveguide medium, and a second upconversion chromophore in contact with the second waveguide medium, wherein the second upconversion chromophore has a second absorption spectrum and a second emission spectrum, wherein the second absorption spectrum and the second emission spectrum do not overlap, and wherein the first absorption spectrum and the second absorption spectrum do not substantially overlap. In an embodiment, a taper provided between the first waveguide and the second waveguide, wherein a refractive index of the taper is higher than a refractive index of the first waveguide.

In another embodiment, the upconversion photoluminescent solar concentrator device also includes a photovoltaic device connected to the first waveguide and the second waveguide, wherein the first emission spectrum and the second emission spectrum overlap with each other, and wherein the first emission spectrum and the second emission spectrum overlap with an absorption wavelength of the photovoltaic device for converting radiation to electrical energy.

In an embodiment, the upconversion photoluminescent solar concentrator device includes a first taper connected to the first waveguide, wherein a refractive index of the first taper is higher than a refractive index of the first waveguide, a second taper connected to the second waveguide, wherein a refractive index of the second taper is higher than a refractive index of the second waveguide.

In an embodiment, the upconversion photoluminescent solar concentrator device includes a first photovoltaic device connected to the first taper, a second photovoltaic device connected to the second taper. The first emission spectrum overlaps with a first absorption wavelength of the first photovoltaic device for converting radiation to electrical energy. The second emission spectrum overlaps with a second absorption wavelength of the second photovoltaic device for converting radiation to electrical energy.

In an embodiment, the upconversion photoluminescent solar concentrator device includes a third photovoltaic device connected to the third taper. The third emission spectrum overlapping with a third absorption wavelength of the third photovoltaic device for converting radiation to electrical energy.

In another embodiment of the upconversion photoluminescent solar concentrator device, the first emission spectrum overlaps with an absorption wavelength of the photovoltaic device for converting radiation to electrical energy.

In another embodiment of the upconversion photoluminescent solar concentrator device, the second emission spectrum overlaps with an absorption wavelength of the photovoltaic device for converting radiation to electrical energy.

In another embodiment, the upconversion photoluminescent solar concentrator device also includes a third waveguide provided under the second waveguide. The third waveguide includes a third waveguide medium, and a third upconversion chromophore in contact with the third waveguide medium, wherein the third upconversion chromophore has a third absorption spectrum and a third emission spectrum, wherein the third absorption spectrum and the third emission spectrum do not substantially overlap, wherein the third absorption spectrum and the first absorption spectrum do not substantially overlap, and wherein the third absorption spectrum and the second absorption spectrum do not substantially overlap. A first taper is connected to the first waveguide, wherein a refractive index of the first taper is higher than a refractive index of the first waveguide. A second taper is connected to the second waveguide, wherein a refractive index of the second taper is higher than a refractive index of the second waveguide. A third taper is connected to the third waveguide, wherein a refractive index of the third taper is higher than a refractive index of the third waveguide.

In another embodiment, the upconversion photoluminescent solar concentrator device also includes a first photovoltaic device connected to the first taper, a second photovoltaic device connected to the second taper, and a third photovoltaic device connected to the third taper, wherein a refractive index of the first photovoltaic device is higher than the refractive index of the first taper, wherein the refractive index of the second photovoltaic device is higher than the refractive index of the second taper, and wherein the refractive index of the third photovoltaic device is higher than the refractive index of the third taper.

In another embodiment of the upconversion photoluminescent solar concentrator device, the first emission spectrum overlaps with an absorption wavelength of the photovoltaic device for converting radiation to electrical energy, the second emission spectrum overlaps with the absorption wavelength of the photovoltaic device for converting radiation to electrical energy, and the third emission spectrum overlaps with the absorption wavelength of the photovoltaic device for converting radiation to electrical energy.

In another embodiment of the upconversion photoluminescent solar concentrator device, the first waveguide, the second waveguide, and the third waveguide each have a rod-like shape axially and a geometric cross-section.

In another embodiment, the upconversion photoluminescent solar concentrator device includes a plurality of waveguides stacked together, wherein each of the plurality of waveguides has a rod-like shape axially and a geometric cross-section. Each of the plurality of waveguides includes a waveguide medium, and an upconversion chromophore in contact with the waveguide medium, wherein the upconversion chromophore is configured to absorb an incident photon and then emit an emitted photon, and the emitted photon has higher energy than the incident photon. The embodiment includes an antireflective coating provided between the plurality of waveguides and a photovoltaic device. The photovoltaic device is provided at an end side of the plurality of waveguides for receiving the emitted photon, wherein an emission spectrum of the upconversion chromophore overlaps with an absorption wavelength of the photovoltaic device for converting radiation to electrical energy.

In another embodiment, the upconversion photoluminescent solar concentrator device includes a second photovoltaic device provided at a second end side of the plurality of waveguides, wherein the emission spectrum of the upconversion chromophore overlaps with an absorption wavelength of the second photovoltaic device for converting radiation to electrical energy.

In another embodiment, a method for converting incident radiation into electrical energy is provided. The embodiment includes absorbing the incident radiation with an upconversion chromophore, emitting an emitted photon from the upconversion chromophore, wherein the emitted photon has higher energy than the incident radiation, directing the emitted photon from the upconversion chromophore to a photovoltaic device using a waveguide, and the photovoltaic device absorbing the emitted photon and converting to electrical energy.

In another embodiment, the method also includes absorbing a second incident radiation with a second upconversion chromophore, wherein the second incident radiation has higher energy than the incident radiation, emitting a second emitted photon from the second upconversion chromophore, wherein the second emitted photon has higher energy than the second incident radiation, directing the second emitted photon from the second upconversion chromophore to the photovoltaic device using a second waveguide, and the photovoltaic device absorbing the second emitted photon and converting to electrical energy.

In another embodiment, the method also includes absorbing a third incident radiation with a third upconversion chromophore, wherein the third incident radiation has higher energy than the incident radiation, emitting a third emitted photon from the third upconversion chromophore, wherein the third emitted photon has higher energy than the third incident radiation, directing the third emitted photon from the third upconversion chromophore to a third photovoltaic device using a third waveguide, and the third photovoltaic device absorbing the third emitted photon and converting to electrical energy.

In another embodiment, the emitted photon and the second emitted photon have the same energy. In another embodiment, the second emitted photon has higher energy than the emitted photon.

In an embodiment, the upconversion photoluminescent solar concentrator device includes a first waveguide including a first waveguide medium, a chromophore layer provided on a surface of the first waveguide, the chromophore layer including a plurality of upconversion chromophores in contact with the first waveguide medium. A second waveguide is provided above the chromophore layer, wherein the second waveguide includes a second waveguide medium, the plurality of upconversion chromophores in contact with the second waveguide medium. A photovoltaic device provided at an end side of the first waveguide and the second waveguide. The first waveguide is configured to direct an emitted photon from one of the plurality of the upconversion chromophores entering the first waveguide towards a photovoltaic device. The second waveguide is configured to direct the emitted photon from one of the plurality of the upconversion chromophores entering the second waveguide towards the photovoltaic device. In an embodiment, the first and/or the second waveguide medium is a liquid. In an embodiment, the first and/or the second waveguide has a rod-like shape axially and a geometric cross-section. In an embodiment, the first and/or the second waveguide medium is one selected from the group consisting of an amorphous silicon dioxide, a silicon dioxide, a clear plastic, a clear liquid, a glass, an organic glass, a glass doped with a Group II-VI semiconductor and acrylic plastic. In an embodiment, the upconversion chromophore is an H-aggregate. In an embodiment, the upconversion chromophore is a rare-earth ion. In an embodiment, an antireflection coating is provided on a side of the first and/or the second waveguide. The antireflection coating may be provided between the waveguide and the chromophore layer. A taper may be provided on a side of the waveguide with the antireflection coating being provided therebetween. In an embodiment, a refractive index of the taper is higher than a refractive index of the first and/or the second waveguide medium. The taper may have a receiving surface towards the first and/or the second waveguide for receiving the emitted photon, and an output surface for outputting the emitted photon, wherein the output surface is smaller than the receiving surface. The taper may be a nanocrystalline diamond. The taper may have a refractive index in a range of 2.0 to 2.6 inclusive. In an embodiment, the photovoltaic device is directly connected to the taper, wherein a refractive index of the photovoltaic device is higher than the refractive index of the taper.

In an embodiment, the absorption spectrum and the emission spectrum of one or more of the plurality of upconversion chromophores overlap. In an embodiment, the absorption spectrum and the emission spectrum of one of the plurality of upconversion chromophores substantially overlap. In an embodiment, the absorption spectrum and the emission spectrum of one or more of the plurality of upconversion chromophores completely overlap. The emitted photon can be trapped in the waveguide that the emitted photon enters such that the probability of reabsorption of the emitted photon by the upconversion chromophore is statistically low, and/or statistically non-existent. Trapping the emitted photon in the waveguide is achieved by a configuration of the waveguide that directs the emitted photon in the waveguide towards the photovoltaic device.

In an embodiment, an upconversion photoluminescent solar concentrator device is an encapsulated solar energy conversion device. The encapsulation includes a first protective sheet and a second protective sheet encapsulating the upconversion photoluminescent solar concentrator device therebetween. In an embodiment, a protective sheet is disposed on a top layer of an upconversion photoluminescent solar concentrator device. In an embodiment, a protective sheet is disposed on a bottom layer of an upconversion photoluminescent solar concentrator device. In an embodiment, a first protective sheet is disposed on a top layer and a second protective sheet is disposed on a bottom layer of an upconversion photoluminescent solar concentrator device, such that the first and second protective sheets sandwich the upconversion photoluminescent solar concentrator device. In an embodiment, any one or more of the protective sheets described herein is made of glass, ethylene vinyl acetate (EVA), and/or other transparent material. In an embodiment, any one or more of the protective sheets described herein includes plurality of upconversion chromophores in the material making up the protective sheet. In an embodiment, the protective sheet made of glass, EVA, and/or other transparent material has a geometric concentrating factor of 1. In an embodiment, only the top protective sheet includes upconversion chromophores. In an embodiment, the bottom protective sheet does not include upconversion chromophores. In an embodiment, both the top and bottom protective sheets include upconversion chromophores. In an embodiment, only the bottom protective sheet includes upconversion chromophores. In an embodiment, the top protective sheet does not include upconversion chromophores. In an embodiment, both the top and bottom protective sheets do not include upconversion chromophores.

### BRIEF DESCRIPTION OF THE DRAWINGS

FIG. 1 shows a side view of an embodiment of an upconversion photoluminescent solar concentrator device.

FIG. 2 shows a side view of an embodiment of an upconversion photoluminescent solar concentrator device.

FIG. 3 shows a side view of an embodiment of an upconversion photoluminescent solar concentrator device.

FIG. 4 shows a side view of an embodiment of an upconversion photoluminescent solar concentrator device.

FIG. 5 shows a side view of an embodiment of an upconversion photoluminescent solar concentrator device.

FIG. 6 shows a side view of an embodiment of an upconversion photoluminescent solar concentrator device.

FIG. 7 shows a side view of an embodiment of an upconversion photoluminescent solar concentrator device.

FIG. 8 shows a side view of an embodiment of an upconversion photoluminescent solar concentrator device.

FIG. 9 shows a side view of an embodiment of an upconversion photoluminescent solar concentrator device.

FIG. 10 shows a side view of an embodiment of an upconversion photoluminescent solar concentrator device.

FIG. 11 shows a side view of an embodiment of an upconversion photoluminescent solar concentrator device.

FIG. 12 shows a side view of an embodiment of an upconversion photoluminescent solar concentrator device.

FIG. 13 shows a perspective view of an embodiment of a waveguide for an upconversion photoluminescent solar concentrator device.

FIG. 14 shows a perspective view of an embodiment of a waveguide for an upconversion photoluminescent solar concentrator device.

FIG. 15(a)-(h) show cross-sectional views of embodiments of waveguides for an upconversion photoluminescent solar concentrator device.

FIG. 16 shows a side view of an embodiment of an upconversion photoluminescent solar concentrator device and absorption and emission spectrums thereof.

FIG. 17 shows a side view of an embodiment of an upconversion photoluminescent solar concentrator device and absorption and emission spectrums thereof.

FIG. 18 shows a side view of an embodiment of an upconversion photoluminescent solar concentrator device.

### DETAILED DESCRIPTION

A method for converting incident radiation into electrical energy includes absorbing the incident radiation with an upconversion chromophore, emitting an emitted photon from the upconversion chromophore, wherein the emitted photon has higher energy than the incident radiation, directing the emitted photon from the upconversion chromophore to a photovoltaic device using a waveguide, and the photovoltaic device absorbing the emitted photon and converting to electrical energy. The method may also include absorbing a second incident radiation with a second upconversion chromophore, wherein the second incident radiation has higher energy than the incident radiation, emitting a second emitted photon from the second upconversion chromophore, wherein the second emitted photon has higher energy than the second incident radiation, directing the second emitted photon from the second upconversion chromophore to the photovoltaic device using a second waveguide, and the photovoltaic device absorbing the second emitted photon and converting to electrical energy. The method may also include absorbing a third incident radiation with a third upconversion chromophore, wherein the third incident radiation has higher energy than the incident radiation, emitting a third emitted photon from the third upconversion chromophore, wherein the third emitted photon has higher energy than the third incident radiation, directing the third emitted photon from the third upconversion chromophore to a third photovoltaic device using a third waveguide, and the third photovoltaic device absorbing the third emitted photon and converting to electrical energy. These embodiments may be carried out by using the embodiment of upconversion photoluminescent solar concentrator devices shown in the Figures and described herein.

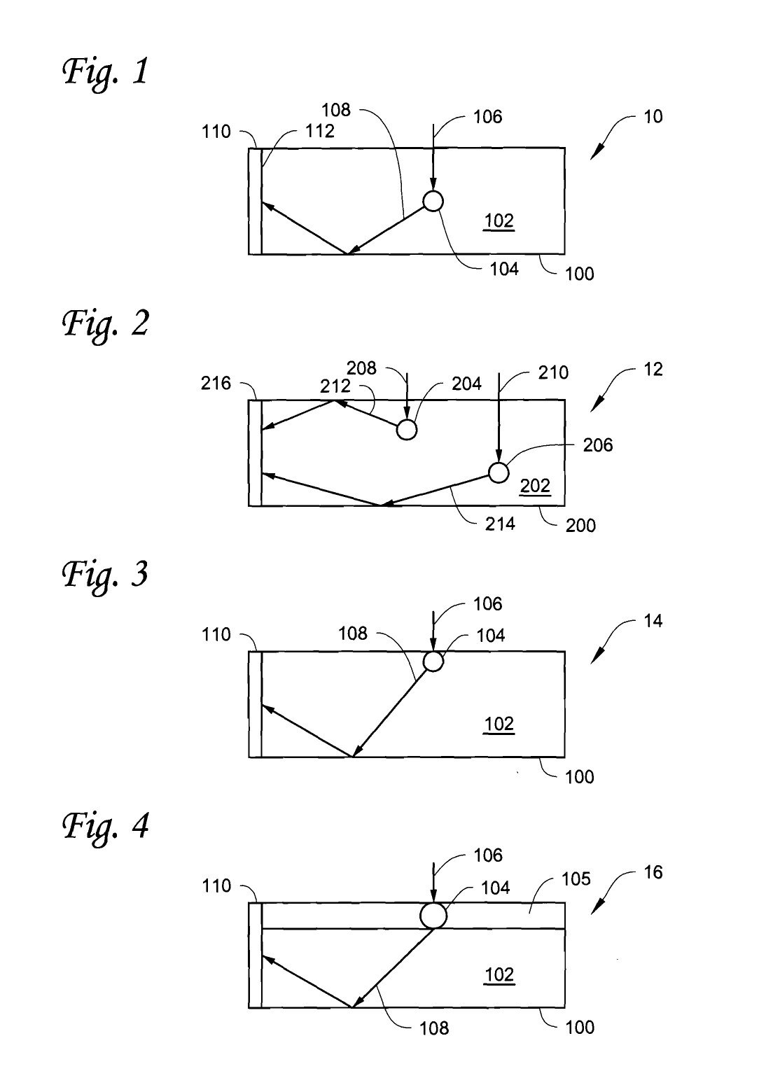

FIG. 1 shows a side view of an embodiment of an upconversion photoluminescent solar concentrator device 10 that includes a waveguide 100. The waveguide 100 includes a waveguide medium 102. An upconversion photoluminescent chromophore 104 is in contact with the waveguide medium 102. The upconversion chromophore 104 is configured to absorb an incident photon 106. The upconversion chromophore 104 is configured to emit an emitted photon 108. FIG. 1 shows the emitted photon 108 being directed towards a photovoltaic device 110 by the waveguide 100 for converting the emitted photon 108 to electrical energy. A taper may be provided at the interface between the waveguide medium 102 and the photovoltaic device 110. A reflective surface 112 may be provided on a side of the waveguide for reflecting the emitted photon.

In an embodiment, the waveguide medium 102 is transparent at a wavelength of the emitted photon 108. The waveguide medium 102 may be glass and/or silicon oxide. Glass and silicon oxide are transparent at the photoluminescent wavelengths that travel through the waveguide medium 102. The waveguide medium 102 may be a product from a sol-gel process. The sol-gel process evolves the sol to a gel-like network producing a sol-gel medium that contains both a liquid phase and a solid phase. The solid phase may form a colloid. The morphology of the solid phase can range anywhere from discrete colloidal particles to continuous chain-like polymer networks. One example of sol-gel medium is amorphous silicon dioxide. The sol-gel medium advantageously has a refractive index which may be adjusted to match upconversion chromophore 104. Examples of materials for the waveguide medium 102 are, but not limited to, an amorphous silicon dioxide, a clear plastic, a clear liquid, silicon dioxide, a glass, an organic glass, a glass doped with a Group II-VI semiconductor, or acrylic plastic. Examples of Group II-VI semiconductors include, but are not limited to, MgO, MgS, MgSe, MgTe, ZnO, ZnS, ZnSe, ZnTe, CdS, CdSe, CdTe, HgS, HgSe, and HgTe. Acrylic plastic has a relatively low melting point and the upconversion chromophore 104 in contact with the acrylic plastic or embedded within the acrylic plastic would have a reduced risk of heat damage. The waveguide medium 102 may be a solid phase, a liquid phase, a glass phase, or a combination thereof.

When the upconversion photoluminescent chromophore 104 absorbs the incident photon 106, the upconversion photoluminescent chromophore 104 gains energy and enters an excited state. The upconversion photoluminescent chromophore 104 can relax from the excited state to a lower energy state, for example a ground state, by losing energy. One way to lose energy is by emission of an emitted photon 108.

Examples of the upconversion chromophore 104 are, but not limited to, an H-aggregate, a rare-earth ion, a rare-earth ion nanocrystal, a lanthanide chelate and/or a NaYF₄ nanocrystal. Further examples of the upconversion chromophore 104 are, but not limited to, a nanocrystal including neodymium (Nd³⁺), ytterbium (Yb³⁺), erbium (Er³⁺), thulium (Tm³⁺), holmium (Ho³⁺), praseodymium (Pr³⁺), cerium (Ce³⁺), yttrium (Y³⁺), samarium (Sm³⁺), europium (Eu³⁺), gadolinium (Gd³⁺), terbium (Tb³⁺), dysprosium (Dy³⁺), and/or lutetium (Lu³⁺). The emitted photon 108 has higher energy than the incident photon 106. This energy difference is called an anti-Stokes shift. The extra energy may come from dissipation of thermal photons in a crystal lattice. The extra energy may come from the upconversion chromophore 104 absorbing more than one incident photon 106, each absorbed incident photon 106 having lower energy than the emitted photon 108. In a two photon process, the upconversion photoluminescent chromophore 104 absorbs two low energy incident photons 106 and emits a single high energy emitted photon 108. Thus, the upconversion chromophore is configured to absorb a second incident photon after the absorption of the incident photon and then emit the emitted photon, wherein the emitted photon has higher energy than the second incident photon.

A significant portion of the solar spectrum is in the infrared range, or wavelength of from 700 nm to 3000 nm. An upconversion chromophore 104 configured to capture at least a portion of this spectrum and upconvert the energy of the captured photon to a useful wavelength for photovoltaic devices, such as wavelength in the visible spectrum, increases overall device efficiency over devices that downconvert ultraviolet spectrum to the visible, and/or near-infrared spectrum. In an embodiment, the upconversion chromophore 104 is configured to absorb the incident photon 106 having a wavelength in infrared range, and then emit the emitted photon 108 having a wavelength in visible range. Infrared range includes near-infrared (NIR), short-wavelength infrared (SWIR), mid-wavelength infrared (MWIR), long-wavelength infrared (LWIR), and far infrared (FIR). In an embodiment, infrared range is wavelength range of from 700 nm to 1,000 μm inclusive. In an embodiment, infrared range is wavelength range of from 700 nm to 1400 nm inclusive. In an embodiment, infrared range is wavelength range of from 700 nm to 3000 nm inclusive. In an embodiment, infrared range is wavelength range of from 1000 nm to 1400 nm inclusive. In an embodiment, infrared range is wavelength range of from 1000 nm to 3000 nm inclusive. In an embodiment, infrared range is wavelength range of from 1400 nm to 3000 nm inclusive. In an embodiment, infrared range is wavelength range of from 3 μm to 8 μm inclusive. In an embodiment, infrared range is wavelength range of from 8 μm to 15 μm inclusive. In an embodiment, infrared range is wavelength range of from 15 μm to 1,000 μm inclusive.

Examples of the photovoltaic device 110 are, but not limited to, a photovoltaic cell, quantum dot (QD), a quantum well photovoltaic device, a AlGaAs/GaAs quantum well photovoltaic device, a direct band gap photovoltaic device, a silicon-based photovoltaic device, and/or a Group III-V direct band gap photovoltaic device.

FIG. 2 shows a side view of an embodiment of an upconversion photoluminescent solar concentrator device 12 that is similar to the upconversion photoluminescent solar concentrator device 10 shown in FIG. 1. FIG. 2 shows the upconversion photoluminescent solar concentrator device 12 including a waveguide 200 and a waveguide medium 202. A first upconversion photoluminescent chromophore 204 and a second photoluminescent chromophore 206 are in contact with the waveguide medium 202. The first and second upconversion chromophores 204, 206 are each configured to absorb first and second incident photons 208, 210, respectively. The first and second upconversion chromophores 204, 206 are each configured to emit first and second emitted photons 212, 214, respectively. First and second emitted photons 212, 214 having substantially equal energies for absorption by the photovoltaic device 216. First and second emitted photons 212, 214 each have wavelengths that are within the absorption spectrum range of the photovoltaic device 216. FIG. 2 shows the first and second emitted photons 212, 214 being directed towards a photovoltaic device 216 by the waveguide 200 for the photovoltaic device 216 for converting the first and second emitted photons 212, 214 to electrical energy. A taper may be provided at the interface between the waveguide medium 202 and the photovoltaic device 216.

In an embodiment, the second emitted photon 214 has higher energy than the second incident photon 210. In an embodiment, the second incident photon 210 has higher energy than the first incident photon 208. In another embodiment, the first emitted photon 212 and the second emitted photon 214 have the same energy.

FIG. 3 shows a side view of an embodiment of an upconversion photoluminescent solar concentrator device 14 that is similar to the upconversion photoluminescent solar concentrator device 10 shown in FIG. 1. In FIG. 3, same labels have been used for identifying structures that are similar to those shown in FIG. 1. FIG. 1 shows the upconversion chromophore 104 embedded in the waveguide medium 102, and in contact with the waveguide medium 102. FIG. 3 shows the upconversion chromophore 104 provided at a surface of the waveguide medium 102, and in contact with the waveguide medium 102.

When the waveguide medium is a liquid, the upconversion chromophore is suspended in the liquid. FIGS. 1-3 can be also understood as showing upconversion chromophores suspended in the waveguide medium, wherein the waveguide medium is a liquid.

FIG. 4 shows a side view of an embodiment of an upconversion photoluminescent solar concentrator device 16 that is similar to the upconversion photoluminescent solar concentrator device 14 shown in FIG. 3. In FIG. 4, same labels have been used for identifying structures that are similar to those shown in FIG. 3. The upconversion photoluminescent solar concentrator device 16 includes a waveguide 100. FIG. 4 shows the upconversion chromophore 104 is provided as a film, or a layer 105, or a sheet, on a surface of the waveguide medium 102, and in contact with the waveguide medium 102. For example, the layer 105 is a layer having a plurality of upconversion chromophores 104 applied to a surface of the sol-gel medium 102.

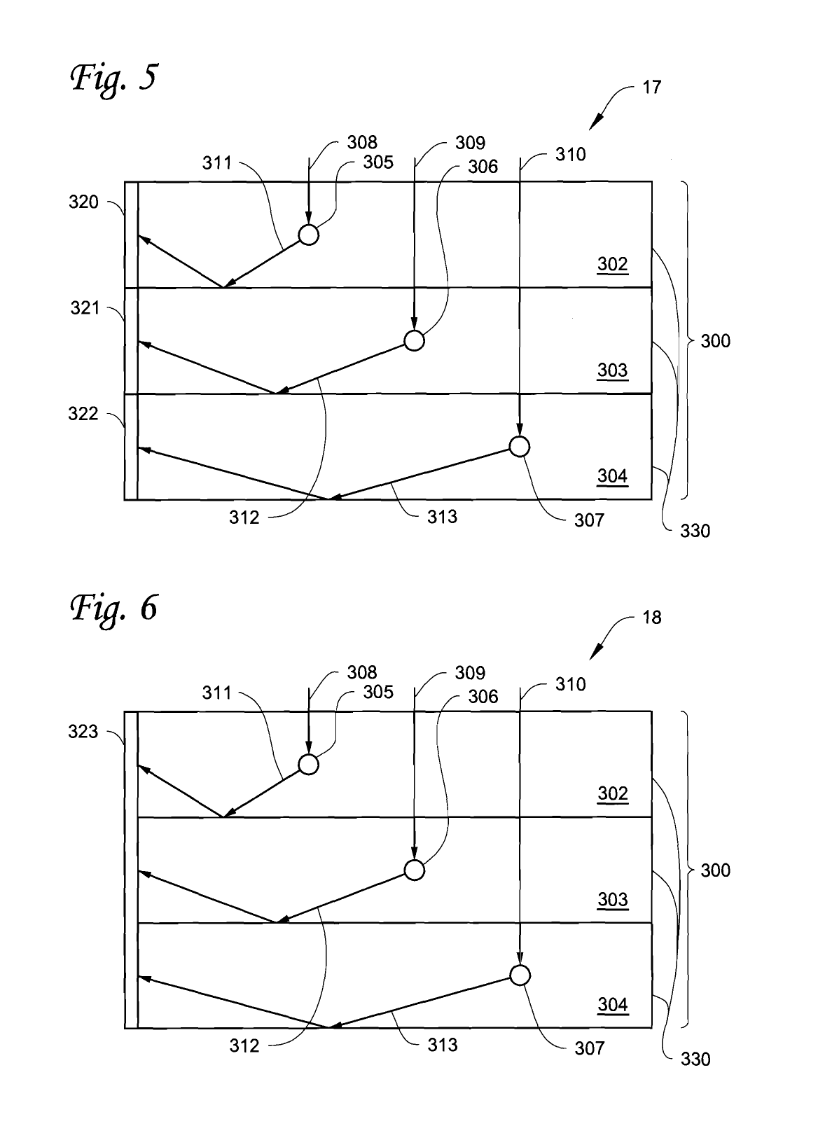

FIG. 5 shows a side view of an embodiment of an upconversion photoluminescent solar concentrator device 17. The upconversion photoluminescent solar concentrator device 17 includes a plurality of waveguides 300. FIG. 5 shows three waveguides 300, wherein the three waveguides 300 are stacked, second waveguide being stacked under the first waveguide, the third waveguide being stacked under the first waveguide. The upconversion photoluminescent solar concentrator device 17 may have more or fewer waveguides. Each of the plurality of waveguides 300 includes a waveguide medium 302, 303, 304. The waveguide medium 302, 303, 304 may be the same material. The waveguide medium 302, 303, 304 may be different material from each other. Upconversion photoluminescent chromophores 305, 306, 307 are each in contact with their respective waveguide mediums 302, 303, 304. The upconversion chromophores 305, 306, 307 are each configured to absorb an incident photon 308, 309, 310, respectively. The upconversion chromophores 305, 306, 307 are each configured to emit an emitted photon 311, 312, 313, respectively. FIG. 5 shows each of the emitted photons 311, 312, 313 being directed towards photovoltaic devices 320, 321, 322 by the plurality of waveguides 300. The photovoltaic devices 320, 321, 322 convert the emitted photons 311, 312, 313 to electrical energy. One or more tapers may be provided at the interfaces between each and/or all of the waveguide mediums 302, 303, 304 and the photovoltaic devices 320, 321, 322. One or more tapers may be provided at the interfaces between the waveguide mediums 302, 303, 304. A reflective surface 330 may be provided on one or more side of the plurality of waveguides 300 for reflecting the emitted photons 311, 312, 313.

FIG. 6 shows a side view of an embodiment of an upconversion photoluminescent solar concentrator device 18 that is similar to the upconversion photoluminescent solar concentrator device 17 shown in FIG. 5. In FIG. 6, same labels have been used for identifying structures that are similar to those shown in FIG. 5. FIG. 6 shows an embodiment of the upconversion photoluminescent solar concentrator device 18 that has a single photovoltaic device 323 instead of multiple photovoltaic devices 320, 321, 322 (as shown in FIG. 5). FIG. 6 shows each of the emitted photons 311, 312, 313 being directed towards the photovoltaic device 323 by the plurality of waveguides 300. One or more tapers may be provided at the interfaces between each and/or all of the waveguide mediums 302, 303, 304 and the photovoltaic device 323.

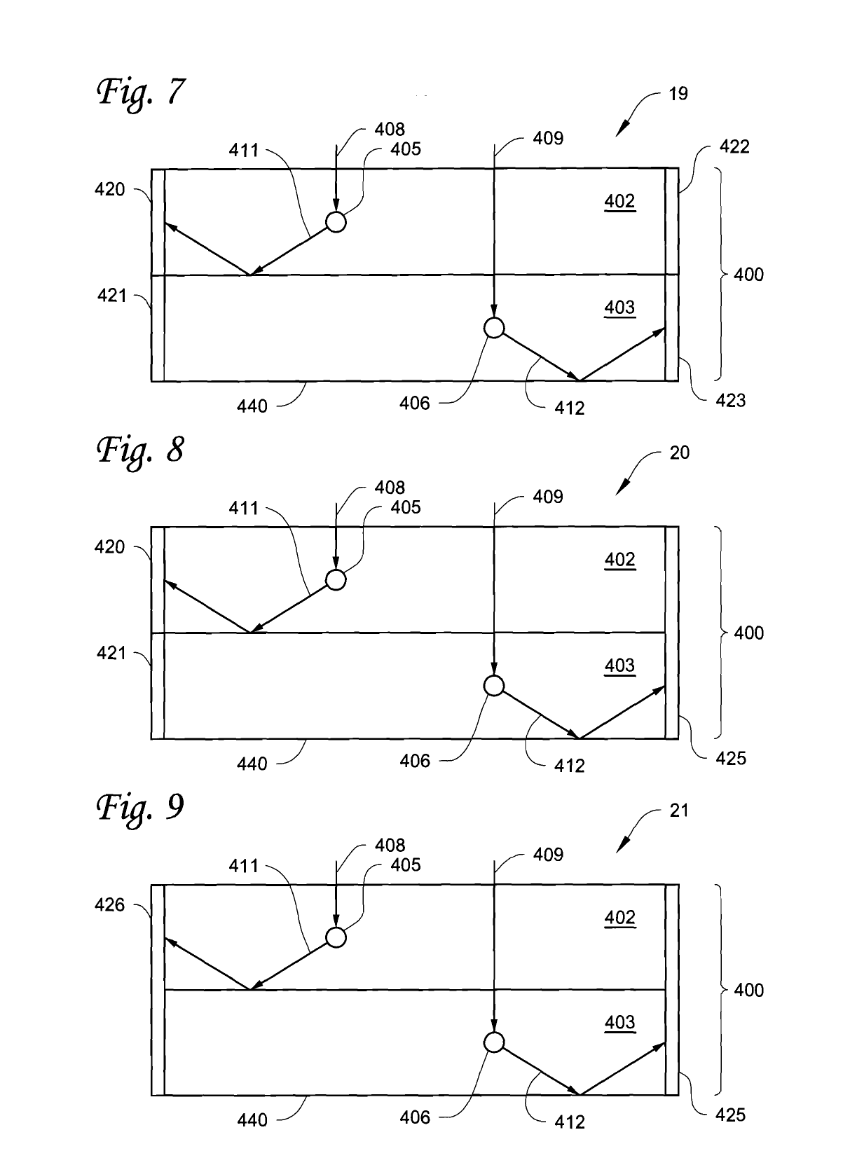

FIG. 7 shows a side view of an embodiment of an upconversion photoluminescent solar concentrator device 19. The upconversion photoluminescent solar concentrator device 19 includes a plurality of waveguides 400. FIG. 7 shows two waveguides 400, wherein the two waveguides 400 are stacked, second waveguide being under the first waveguide. When a waveguide is said to be under another waveguide, the term under describes being beneath in a direction from a source of an incident photon, so that the incident photon must traverse through the first waveguide before the incident photon enters the waveguide that is under the first waveguide. The upconversion photoluminescent solar concentrator device 19 may have more waveguides stacked together. Each of the plurality of waveguides 400 includes a waveguide medium 402, 403. Upconversion photoluminescent chromophores 405, 406 are each in contact with their respective waveguide mediums 402, 403. The upconversion chromophores 405, 406 are each configured to absorb an incident photon 408, 409, respectively. The upconversion chromophores 405, 406 are each configured to emit an emitted photon 411, 412, respectively. FIG. 7 shows each of the emitted photons 411, 412 being directed towards photovoltaic devices 420, 421, 422, 423 by the plurality of waveguides 400. Two of the photovoltaic devices 420, 422 are provided at opposing end sides of the same waveguide 400. Two of the photovoltaic devices 421, 423 are provided at opposing end sides of the same waveguide 400. The photovoltaic devices 420, 421, 422, 423 convert the emitted photons 411, 412 to electrical energy. One or more tapers may be provided at the interfaces between each and/or all of the waveguide mediums 402, 403 and the photovoltaic devices 420, 421, 422, 423. A reflective surface 440 may be provided on one or more side of the plurality of waveguides 400 for reflecting the emitted photons 411, 412 towards the photovoltaic devices 420, 421, 422, 423.

FIG. 8 shows a side view of an embodiment of an upconversion photoluminescent solar concentrator device 20 that is similar to the upconversion photoluminescent solar concentrator device 19 shown in FIG. 7. In FIG. 8, same labels have been used for identifying structures that are similar to those shown in FIG. 7. FIG. 8 shows a single photovoltaic device 425 provided at an end side of the plurality of waveguides 400, instead of the multiple photovoltaic devices 422, 423 (as shown in FIG. 7). The photovoltaic devices 420, 421 are provided at opposing end side away from the single photovoltaic device 425.

FIG. 9 shows a side view of an embodiment of an upconversion photoluminescent solar concentrator device 21 that is similar to the upconversion photoluminescent solar concentrator device 20 shown in FIG. 8. In FIG. 9, same labels have been used for identifying structures that are similar to those shown in FIG. 8. FIG. 9 shows a single photovoltaic device 426 provided at an end side of the plurality of waveguides 400, instead of the multiple photovoltaic devices 420, 421 (as shown in FIGS. 7 and 8). The photovoltaic devices 425, 426 are provided at opposing end sides of the plurality of waveguides 400.

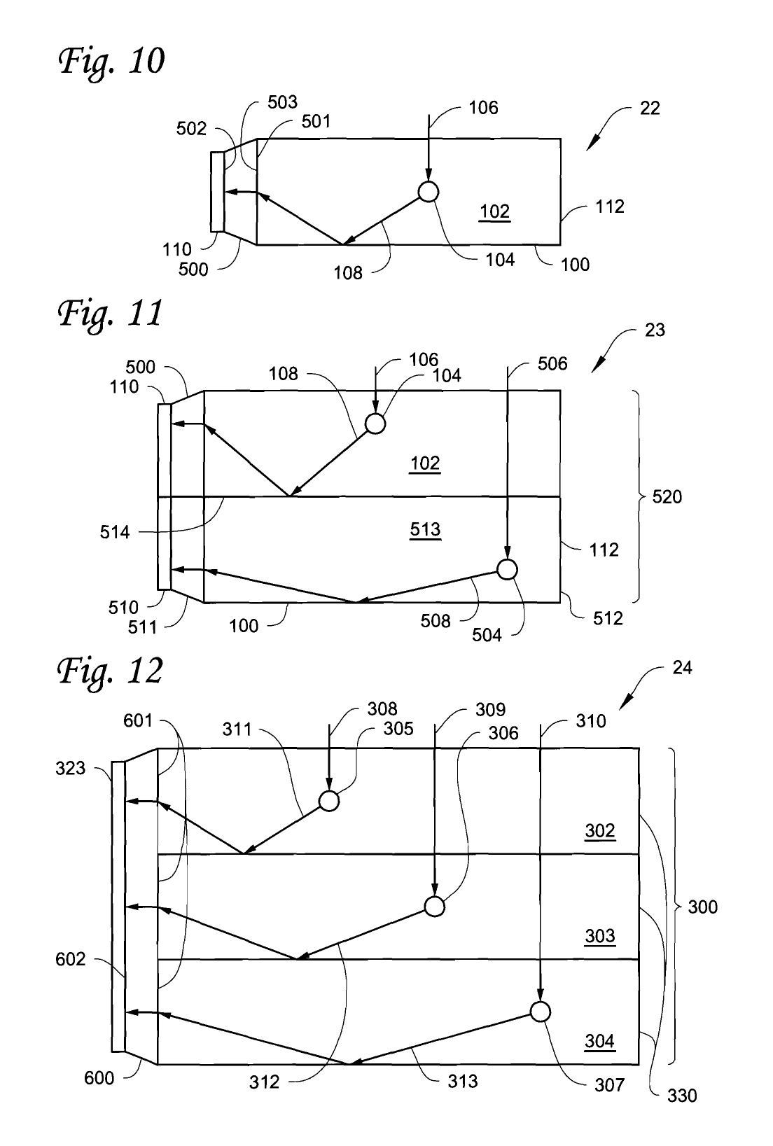

FIG. 10 shows a side view of an embodiment of an upconversion photoluminescent solar concentrator device 22 that is similar to the upconversion photoluminescent solar concentrator device 10 shown in FIG. 1. In FIG. 10, same labels have been used for identifying structures that are similar to those shown in FIG. 1. FIG. 10 shows the emitted photon 108 being directed towards a photovoltaic device 110 by the waveguide 100. The embodiment shown in FIG. 10 includes interface elements between the waveguide 100 and the photovoltaic device 110. FIG. 10 shows a taper 500 provided on an antireflection coating 501 at an end side of the waveguide 100. The antireflection coating 501 is provided on a side of the waveguide at the interface between the taper 500 and the waveguide 100 and/or the waveguide medium 102. Alternatively, the taper 500 may be provided to be directly in contact with the waveguide 100 and/or the waveguide medium 102.

The refractive index of the taper 500 is higher than a refractive index of the waveguide medium 102. The photovoltaic device 110 is provided to receive luminescence from the taper 500 side. The photovoltaic device 110 may be directly connected to the taper 500. Alternatively, the photovoltaic device 110 may be connected to the taper 500 with an antireflection coating provided between the photovoltaic device 110 and the taper 500.

The luminescence hits the exit face of the waveguide 100 at all angles and therefore cannot be further concentrated in the waveguide medium 102 of the same refractive index. However, by including a taper 500 of a transparent medium having higher refractive index than the waveguide medium 102 further concentration of the luminescence to about 5 times is possible, facilitating an overlapping of different units for avoiding shading loss.

The taper 500 has an output surface 502 for outputting the emitted photon towards the photovoltaic device 110, and a receiving surface 503 towards the waveguide for receiving the emitted photon 108. In an embodiment, the taper 500 has an output surface 502 that is smaller than the receiving surface 503. The taper 500 may be a nanocrystalline diamond. The taper 500 may be of a material having a refractive index in a range of 2.0 to 2.6 inclusive. A reflective surface 112 may be provided on a second side of the waveguide 100 for reflecting the emitted photon 108 towards the taper 500. In another embodiment, the upconversion photoluminescent solar concentrator device 22 also includes a photovoltaic device 110 directly connected to the taper 500, wherein a refractive index of the photovoltaic device 110 is higher than the refractive index of the taper 500.

FIG. 11 shows a side view of an embodiment of an upconversion photoluminescent solar concentrator device 23, wherein the waveguide 100 shown in FIG. 10 is stacked on top of another waveguide 512, forming a plurality of waveguides 520. The second waveguide 512 is under the first waveguide 100. The second waveguide includes a second upconversion photoluminescent chromophore 504 is in contact with the second waveguide medium 513. The second upconversion chromophore 504 is configured to absorb a second incident photon 506. The second upconversion chromophore 504 is configured to emit a second emitted photon 508. FIG. 11 shows the second emitted photon 508 being directed towards a second photovoltaic device 510 by the plurality of waveguides 520 for converting the emitted photon 508 to electrical energy. FIG. 11 shows a second taper 511 provided at an end side of the second waveguide 512. The antireflection coating may provided on a side of the waveguide at the interface between the taper 511 and the second waveguide 512 and/or the waveguide medium 513. Alternatively, the taper 511 may be provided to be directly in contact with the second waveguide 512 and/or the waveguide medium 513. FIG. 11 shows the second photovoltaic device 510 being provided on the second taper 511 at a surface away from the second waveguide 512. A taper 514 is provided at the interface between the waveguide mediums 102, 513.

The refractive index of the first taper 500 is higher than a refractive index of the first waveguide 100, the refractive index of the second taper 511 is higher than a refractive index of the second waveguide 512, and a photovoltaic device connected to the first taper and the second taper. A refractive index of the first photovoltaic device 110 is higher than the refractive index of the first taper 500. The refractive index of the second photovoltaic device 570 is higher than the refractive index of the second taper 511.

FIG. 12 shows a side view of an embodiment of an upconversion photoluminescent solar concentrator device 24 that is similar to the upconversion photoluminescent solar concentrator device 18 shown in FIG. 6. In FIG. 12, same labels have been used for identifying structures that are similar to those shown in FIG. 6. FIG. 12 shows each of the emitted photons 311, 312, 313 being directed towards the photovoltaic device 323 by the plurality of waveguides 300. FIG. 12 shows a taper 600 being provided at the interfaces between the plurality of waveguides 300 and the photovoltaic device 323. FIG. 12 shows a taper 600 provided on an antireflection coating 601 at an end side of the plurality of waveguides 300. The antireflection coating 601 is provided on a side of the plurality of waveguides 300 at the interface between the taper 600 and the plurality of waveguides 300 and/or the waveguide mediums 302, 303, 304. Alternatively, the taper 600 may be provided to be directly in contact with the plurality of waveguides 300 and/or the waveguide mediums 302, 303, 304. An antireflection coating may be provided between the taper 323 and the taper 600 therebetween 602.

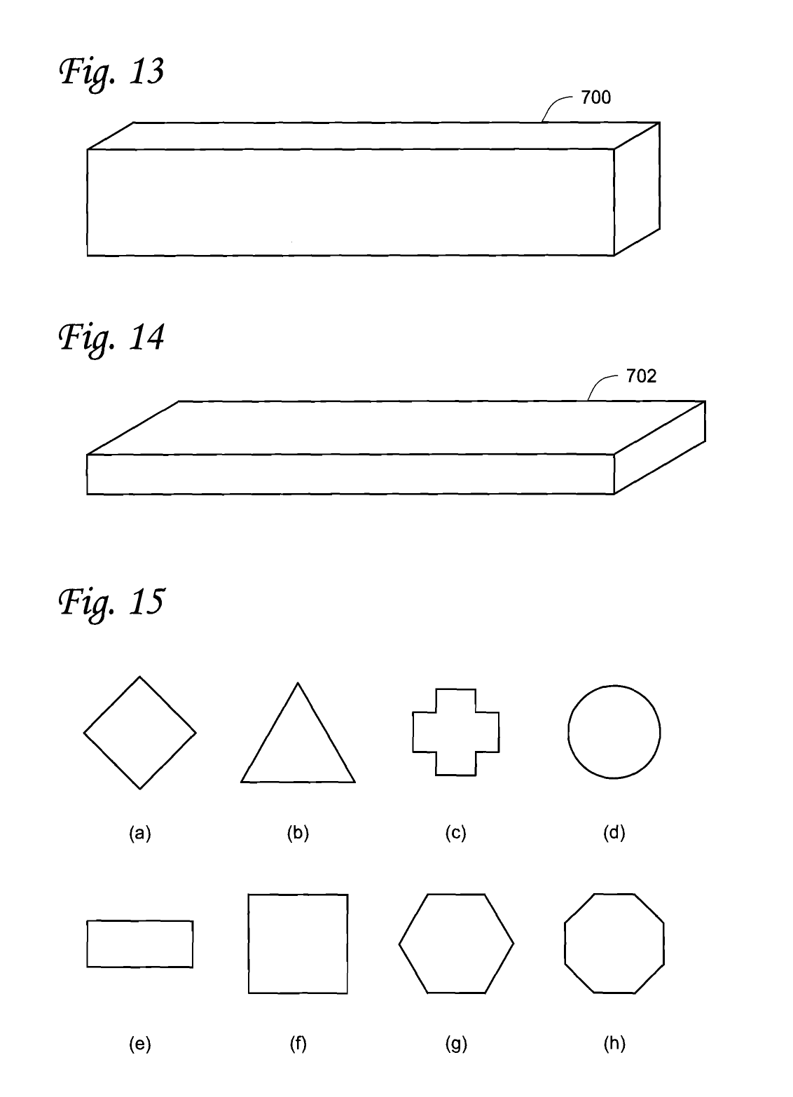

FIG. 13 shows a perspective view of an embodiment of a waveguide 700 having a rod-like shape axially and a geometric cross-section.

FIG. 14 shows a perspective view of another embodiment of a waveguide 702 having a rod-like shape axially and a geometric cross-section. In an embodiment, a height to a width ratio is 1:1000. In an embodiment, a height to a width ratio is 1:>1000.

FIG. 15(a)-(h) show examples of cross-sectional views for a waveguide. Geometric cross-section allows for efficient stacking of the waveguides. FIG. 15(a) shows a geometric cross-section being a parallelogram. FIG. 15(b) shows a geometric cross-section being a triangle. FIG. 15(c) shows a geometric cross-section being a cross. FIG. 15(d) shows a geometric cross-section being a circle. FIG. 15(e) shows a geometric cross-section being a rectangle. FIG. 15(f) shows a geometric cross-section being a square. FIG. 15(g) shows a geometric cross-section being a hexagon. FIG. 15(h) shows a geometric cross-section being a octagon.

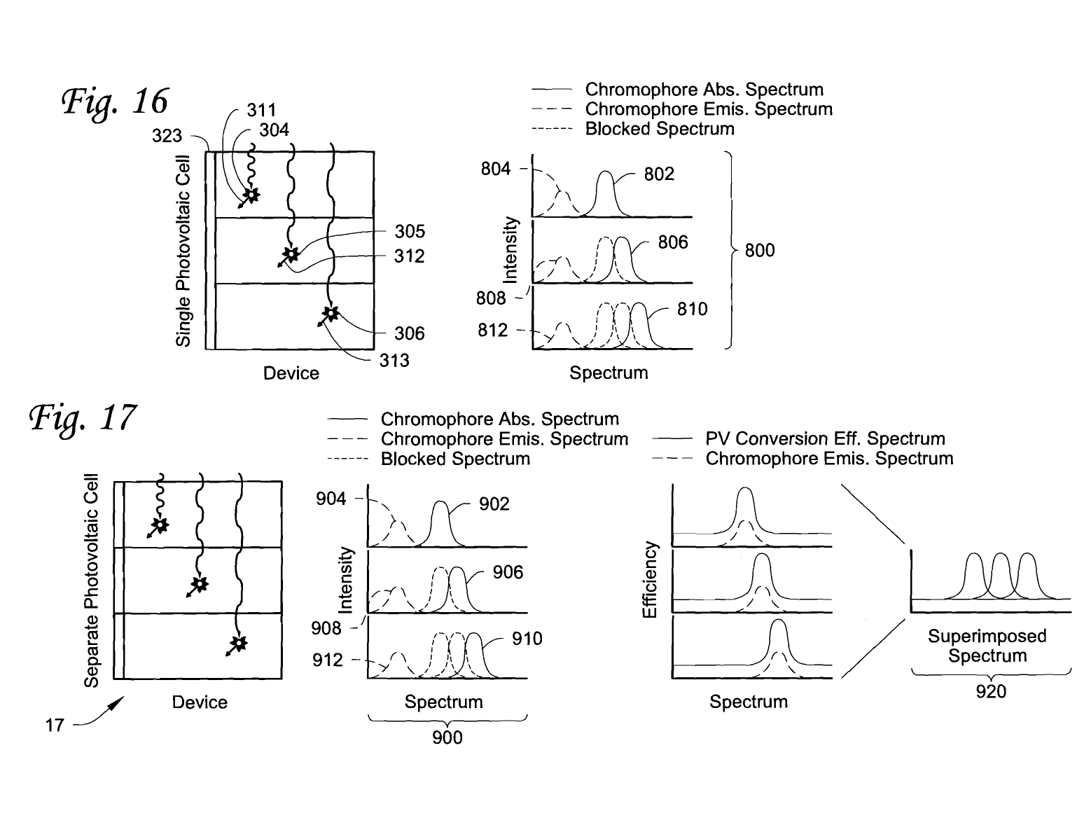

FIG. 16 shows a side view of an embodiment of an upconversion photoluminescent solar concentrator device 18, 24 (FIGS. 6 and 12) and absorption and emission spectrums thereof. The spectrum graph 800 shows Wavelength (λ) vs. Intensity at each of the waveguides. The spectrum graph 800 shows the first absorption spectrum 802 and the first emission spectrum 804 of the first upconversion chromophore 305, the second absorption spectrum 806 and the second emission spectrum 808 of the second upconversion chromophore 306, and the third absorption spectrum 810 and the third emission spectrum 812 of the third upconversion chromophore 307.

Incident light of increasing wavelengths 802, 806, 810 are received by respective waveguides. Upconversion photoluminescent chromophores 304, 305, 306 tuned to absorb wavelengths of incident radiation 802, 806, 810 and emit photons 311, 312, 313 at respective blue-shifted wavelengths 804, 808, 812. This blue-shifted radiation 804, 808, 812 is internally reflected within the respective waveguides and directed towards the photovoltaic device 323.

Substantial overlap is defined to be when an overlap between two spectra is equal to or more than 50%. No substantial overlap is defined to be when an overlap between two spectra is less than 50%. No overlap is defined to be when the overlap between two spectra is less than 90%.

FIG. 16 shows that the first absorption spectrum 802 and the first emission spectrum 804 do not substantially overlap, the second absorption spectrum 806 and the second emission spectrum 808 do not substantially overlap, and the third absorption spectrum 810 and the third emission spectrum 812 do not substantially overlap.

FIG. 16 shows that the first absorption spectrum 802 and the first emission spectrum 804 do not overlap, the second absorption spectrum 806 and the second emission spectrum 808 do not overlap, and the third absorption spectrum 810 and the third emission spectrum 812 do not overlap.

FIG. 16 shows that the first absorption spectrum 802 and the second absorption spectrum 806 do not substantially overlap, and second absorption spectrum 806 and the third absorption spectrum 810 do not substantially overlap. FIG. 16 shows that the first absorption spectrum 802 and the third absorption spectrum 810 do not overlap.

FIG. 16 shows the first emission spectrum 804 and the second emission spectrum 808 having substantial overlap, the second emission spectrum 808 and the third emission spectrum 812 having substantial overlap, and the first emission spectrum 804 and the third emission spectrum 812 having substantial overlap. The first, second, and third emission spectra 804, 808, 812 overlap with an absorption wavelength of the photovoltaic device 323 for converting radiation to electrical energy.

FIG. 17 shows a side view of an embodiment of an upconversion photoluminescent solar concentrator device 17 (FIG. 5) and absorption and emission spectrums thereof. The spectrum graph 900 shows Wavelength (λ) vs. Intensity at each of the waveguides. The spectrum graph 900 shows the first absorption spectrum 902 and the first emission spectrum 904 of the first upconversion chromophore 305, the second absorption spectrum 906 and the second emission spectrum 908 of the second upconversion chromophore 306, and the third absorption spectrum 910 and the third emission spectrum 912 of the third upconversion chromophore 307. The first absorption spectrum 902 and the first emission spectrum 904 do not substantially overlap, the second absorption spectrum 906 and the second emission spectrum 908 do not substantially overlap, and the third absorption spectrum 910 and the third emission spectrum 912 do not substantially overlap. The first absorption spectrum 902 and the first emission spectrum 904 do not overlap, the second absorption spectrum 906 and the second emission spectrum 908 do not overlap, and the third absorption spectrum 910 and the third emission spectrum 912 do not overlap. The first absorption spectrum 902 and the second absorption spectrum 906 do not substantially overlap, and second absorption spectrum 906 and the third absorption spectrum 910 do not substantially overlap. FIG. 16 shows that the first absorption spectrum 902 and the third absorption spectrum 910 do not overlap. The first emission spectrum 904 and the second emission spectrum 908 have no substantial overlap, the second emission spectrum 908 and the third emission spectrum 912 have no substantial overlap, and the first emission spectrum 904 and the third emission spectrum 912 have no substantial overlap. The first, second, and third emission spectra 904, 908, 912 each overlap with an absorption wavelength of their respective the photovoltaic devices 320, 321, 322 for converting radiation to electrical energy. Lower layer waveguides of the device 17 absorb and emit sequentially longer wavelengths of light. Upper layer waveguides absorb radiation so that these radiation wavelengths are not significantly seen by lower layers. Thus, effectively, the wavelengths of light absorbed by the upper layer chromophores are “blocked” to the lower layers. The chromophore radiation emission is tuned to the most efficient part of the power conversion spectrum of the corresponding type of photovoltaic device. The superimposed spectrum 920 shows how the device 17 can effectively create an efficient power conversion system.

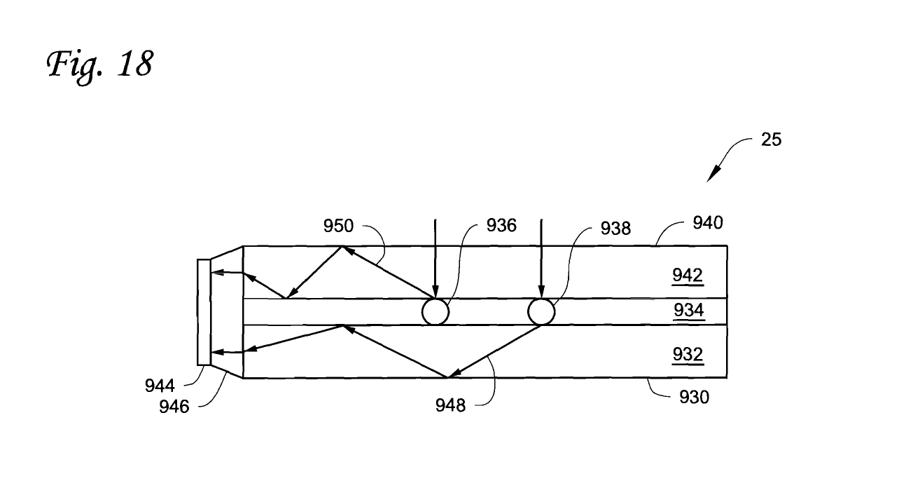

FIG. 18 shows a side view of an embodiment of an upconversion photoluminescent solar concentrator device 25. The upconversion photoluminescent solar concentrator device 25 includes a first waveguide 930 including a first waveguide medium 932, a chromophore layer 934 provided on a surface of the first waveguide 930, the chromophore layer 934 including a plurality of upconversion chromophores 936, 938 in contact with the first waveguide medium 932. A second waveguide 940 is provided above the chromophore layer 934, wherein the second waveguide 940 includes a second waveguide medium 942, the plurality of upconversion chromophores 936, 938 are in contact with the second waveguide medium 942. A photovoltaic device 944 is provided at an end side of the first waveguide 930 and the second waveguide 940. FIG. 18 shows a taper 946 provided between the photovoltaic device 944 and the first and second waveguides 930, 940. The first waveguide 930 is configured to direct an emitted photon 948 from one of the plurality of the upconversion chromophores 938 entering the first waveguide 930 towards a photovoltaic device 944. The second waveguide 940 is configured to direct an emitted photon 950 from one of the plurality of the upconversion chromophores 936 entering the second waveguide 940 towards the photovoltaic device 944. An antireflection coating may be provided on a side of the first and/or the second waveguides 930, 940. The antireflection coating may be provided between the first waveguide 930 and the chromophore layer 934. The antireflection coating may be provided between the second waveguide 940 and the chromophore layer 934. The absorption spectrum and the emission spectrum of the plurality of upconversion chromophores 936, 938 may overlap, may substantially overlap, and/or completely overlap. The emitted photon 948, 950 can be trapped in the waveguide 930, 940 that the emitted photon 948, 950 enters such that the probability of reabsorption by the upconversion chromophore 936, 938 is statistically low, and/or statistically non-existent. Trapping the emitted photon 948, 950 in the waveguide 930, 940 is achieved by a configuration of the waveguide 930, 940 that directs the emitted photon 948, 950 in the waveguide 930, 940 towards the photovoltaic device 944. Examples of the configuration are, but not limited to, a geometry of the waveguide 930, 940 where in a height to a length ratio of the waveguide being 1:1000, type of waveguide medium 932, 942, refractive index difference between the waveguide medium 932, 942 and the chromophore layer 934, antireflection coating provided between the waveguide 930, 940 and the chromophore layer 934, and/or a combination thereof.

Preferred embodiments have been described. Those skilled in the art will appreciate that various modifications and substitutions are possible, without departing from the scope of the invention as claimed and disclosed, including the full scope of equivalents thereof.

What is claimed is:

1. An upconversion photoluminescent solar concentrator device, comprising:
a waveguide including a waveguide medium, and
an upconversion chromophore in contact with the waveguide medium,
wherein the upconversion chromophore is configured to absorb an incident photon,
wherein the upconversion chromophore is configured to emit an emitted photon,
wherein the emitted photon has higher energy than the incident photon,
wherein the upconversion chromophore has an absorption spectrum and an emission spectrum that do not overlap.

2. The upconversion photoluminescent solar concentrator device according to claim 1,
wherein the upconversion chromophore is embedded in the waveguide medium.

3. The upconversion photoluminescent solar concentrator device according to claim 1,
wherein the upconversion chromophore is provided at a surface of the waveguide medium.

4. The upconversion photoluminescent solar concentrator device according to claim 1,
wherein the upconversion chromophore is provided as a layer on a surface of the waveguide medium.

5. The upconversion photoluminescent solar concentrator device according to claim 1,
wherein the waveguide medium is a liquid, and
wherein the upconversion chromophore is suspended in the liquid.

6. The upconversion photoluminescent solar concentrator device according to claim 1,
wherein the waveguide has a rod-like shape axially and a geometric cross-section.

7. The upconversion photoluminescent solar concentrator device according to claim 1,
wherein the waveguide medium is one selected from the group consisting of an amorphous silicon dioxide, a silicon dioxide, a clear plastic, a clear liquid, a glass, an organic glass, a glass doped with a Group II-VI semiconductor and acrylic plastic.

8. The upconversion photoluminescent solar concentrator device according to claim 1,
wherein the upconversion chromophore is a H-aggregate.

9. The upconversion photoluminescent solar concentrator device according to claim 1,
wherein the upconversion chromophore is a rare-earth ion.

10. The upconversion photoluminescent solar concentrator device according to claim 1,
wherein an antireflection coating is provided on a side of the waveguide, and
wherein a taper is provided on the antireflection coating,
wherein a refractive index of the taper is higher than a refractive index of the waveguide medium.

11. The upconversion photoluminescent solar concentrator device according to claim 10,
wherein the taper has a receiving surface towards the waveguide for receiving the emitted photon, and an output surface for outputting the emitted photon,
wherein the output surface is smaller than the receiving surface.

12. The upconversion photoluminescent solar concentrator device according to claim 10,
wherein the taper is a nanocrystalline diamond.

13. The upconversion photoluminescent solar concentrator device according to claim 10,
wherein the taper has a refractive index in a range of 2.0 to 2.6 inclusive.

14. The upconversion photoluminescent solar concentrator device according to claim 10, further comprising a photovoltaic device directly connected to the taper, wherein a refractive index of the photovoltaic device is higher than the refractive index of the taper.

15. The upconversion photoluminescent solar concentrator device according to claim 1, further comprising a second upconversion chromophore,
wherein the second upconversion chromophore absorbs a second incident photon and emits a second emitted photon,
wherein the second emitted photon has higher energy than the second incident photon,
wherein the second incident photon has higher energy than the incident photon,
wherein the upconversion chromophore has a first absorption spectrum and a first emission spectrum,
wherein the first absorption spectrum and the first emission spectrum do not substantially overlap,
wherein the second upconversion chromophore has a second absorption spectrum and a second emission spectrum, and
wherein the second absorption spectrum and the second emission spectrum do not substantially overlap.

16. The upconversion photoluminescent solar concentrator device according to claim 15,
wherein the first absorption spectrum and the second absorption spectrum do not substantially overlap.

17. The upconversion photoluminescent solar concentrator device according to claim 16,
wherein the first emission spectrum and the second emission spectrum overlap.

18. An upconversion photoluminescent solar concentrator device, comprising:
a first waveguide including:
a first waveguide medium, and
a first upconversion chromophore in contact with the first waveguide medium,
wherein the first upconversion chromophore has a first absorption spectrum and a first emission spectrum,
wherein the first absorption spectrum and the first emission spectrum do not overlap;
a second waveguide provided under the first waveguide,
wherein the second waveguide includes:
a second waveguide medium, and
a second upconversion chromophore in contact with the second waveguide medium,
wherein the second upconversion chromophore has a second absorption spectrum and a second emission spectrum,
wherein the second absorption spectrum and the second emission spectrum do not overlap, and
wherein the first absorption spectrum and the second absorption spectrum do not substantially overlap.

19. The upconversion photoluminescent solar concentrator device according to claim 18, further comprising a taper provided between the first waveguide and the second waveguide, wherein a refractive index of the taper is higher than a refractive index of the first waveguide.

20. The upconversion photoluminescent solar concentrator device according to claim 18, further comprising:
a third waveguide provided under the second waveguide,
wherein the third waveguide includes:
a third waveguide medium, and
a third upconversion chromophore in contact with the third waveguide medium,
wherein the third upconversion chromophore has a third absorption spectrum and a third emission spectrum,
wherein the third absorption spectrum and the third emission spectrum do not substantially overlap,
wherein the third absorption spectrum and the first absorption spectrum do not substantially overlap, and
wherein the third absorption spectrum and the second absorption spectrum do not substantially overlap;
a first taper connected to the first waveguide, wherein a refractive index of the first taper is higher than a refractive index of the first waveguide;
a second taper connected to the second waveguide, wherein a refractive index of the second taper is higher than a refractive index of the second waveguide; and
a third taper connected to the third waveguide, wherein a refractive index of the third taper is higher than a refractive index of the third waveguide.

21. The upconversion photoluminescent solar concentrator device according to claim 20, further comprising:
a first photovoltaic device connected to the first taper;
a second photovoltaic device connected to the second taper; and
a third photovoltaic device connected to the third taper,
wherein a refractive index of the first photovoltaic device is higher than the refractive index of the first taper,
wherein the refractive index of the second photovoltaic device is higher than the refractive index of the second taper, and
wherein the refractive index of the third photovoltaic device is higher than the refractive index of the third taper.

22. The upconversion photoluminescent solar concentrator device according to claim 21,
wherein the first emission spectrum overlaps with an absorption wavelength of the first photovoltaic device for converting radiation to electrical energy,
wherein the second emission spectrum overlaps with the absorption wavelength of the second photovoltaic device for converting radiation to electrical energy, and
wherein the third emission spectrum overlaps with the absorption wavelength of the third photovoltaic device for converting radiation to electrical energy.

23. The upconversion photoluminescent solar concentrator device according to claim 21,
wherein the first waveguide, the second waveguide, and the third waveguide each have a rod-like shape axially and a geometric cross-section.

24. An upconversion photoluminescent solar concentrator device, comprising:
a first waveguide including a first waveguide medium;
a chromophore layer provided on a surface of the first waveguide, the chromophore layer including a plurality of upconversion chromophores in contact with the first waveguide medium;
a second waveguide provided above the chromophore layer, wherein the second waveguide includes a second waveguide medium, the plurality of upconversion chromophores in contact with the second waveguide medium;
a photovoltaic device provided at an end side of the first waveguide and the second waveguide,
wherein the first waveguide is configured to direct an emitted photon from one of the plurality of the upconversion chromophores entering the first waveguide towards a photovoltaic device,
wherein the second waveguide is configured to direct the emitted photon from one of the plurality of the upconversion chromophores entering the second waveguide towards the photovoltaic device.
